(19) United States
(12) Patent Application Publication
(10) Pub. No.: US 2012/0034860 A1
(43) Pub. Date: Feb. 9, 2012

(54) DATA CENTER AND COMPUTER STORING RACK THEREFOR

(76) Inventors: Ryosuke Okada, Osaka (JP); Ryuichi Otsuka, Tokyo (JP)

(21) Appl. No.: 13/263,143

(22) PCT Filed: Oct. 18, 2010
(86) PCT No.: PCT/JP2010/068252

§ 371 Date: Oct. 6, 2011

(30) Foreign Application Priority Data
Oct. 23, 2009 (JP) 2009-244340

(51) Int. Cl. H05K 5/02

(52) U.S. Cl. 454/184

(57) ABSTRACT

The problem for the present invention is to provide a data center that can allow computers such as servers or the like to be operated stably and that can greatly reduce energy consumption during operation, and a rack for storage of computers to be used therein. According to the present invention, a data center 1 is provided as a building for installation and operation of computers, and includes an intake area 10 provided with an intake device that sucks external air into the building, an exhaust area 20 provided with an exhaust device that discharges air to the exterior of the building, a dividing wall 40 that separates the intake area 10 from the exhaust area 20, a rack 30 for computer storage installed so as to pierce through a portion of the dividing wall 40, and an air flow control means that controls air flow so that air in the intake area 10 passes through the rack for computer storage 30 and flows to the exhaust area 20.

### TECHNICAL FIELD

The present invention relates to a data center which is a building for installation and operation of computers, and to a rack for storage of computers that are used therein.

### BACKGROUND ART

For some time the electrical power consumption of data centers has been rising along with the increase in the numbers of computers such as servers. Recently, along with the raising of consciousness about environmental problems, attention has focused upon economization of energy in data centers as being a very important subject. Due to this, in recent design of data centers, there has been a demand for keeping down the amount of electrical power used, and also for managing generation of heat and so on.

With a typical data center, as described in JP 2009-63226 A, in order to eliminate the heat generated by the computers, a construction is adopted in which cool air is drawn in from below the floor, hot air is exhausted from the ceiling, and so on. To put it in another manner, the computers are cooled by an air conditioning system that employs air as the cooling medium. In concrete terms, the air which is the cooling medium is circulated within the data center which is sealed, and cooling is implemented by exposing the computers to cold air with an air conditioning system. Thus the air itself that has been heated by the computers is cooled by a cooling system, and then again the computers are exposed to the air.

### SUMMARY DISCLOSURE OF THE INVENTION

Recently, consciousness of environmental problems and of economy of energy has become yet further elevated. Moreover, in the information communication field, due to the rapid increase in the number of internet users and the widespread use of Saas and cloud computing and so on, the use of servers has increased at an accelerating pace. On the other hand, due to progression in the technology of servers themselves, the number of computers that can function while generating less heat than in the prior art, and the number of computers that can function at higher temperatures than in the prior art, have both continued to increase.

In consideration of these factors, the present invention seeks to solve the problem of providing a data center that can allow computers such as servers to operate in a stable manner and that can greatly reduce energy consumption during operation, and of providing a rack for computer storage used in such a data center.

As a result of assiduous investigation performed by the present inventors, the present invention has been formulated as follows:

(1) A data center that is a building for installation and operation of computers, comprising: an intake area comprising an intake device that takes external air into the building; an exhaust area comprising an exhaust device that discharges air to the exterior of the building; a dividing wall that separates between the intake area and the exhaust area; a rack for computer storage, installed so as to pierce through a portion of the dividing wall; and an air flow control means that controls air flow, so as to flow air in the intake area through the rack for computer storage into the exhaust area.

(2) The data center of (1), further comprising an airtight chamber to which the air flow is cut off from the intake area and from the exhaust area, with the airtight chamber being provided with a exit/entrance to the intake area and an exit/entrance to the exhaust area

(3) The data center of (1) or (2), further comprising a second intake area, separate from the above intake area, and comprising an intake device that takes external air into the building; a second dividing wall that separates between the second intake area and the exhaust area; a second rack for computer storage, installed so as to pierce through a portion of the second dividing wall; and a second air flow control means that controls air flow, so as to flow air in the second intake area through the second rack for computer storage into the exhaust area.

(4) The data center of any one of (1) through (3), further comprising a bypass path for air from the exhaust device to the intake device.

(5) The data center of any one of (1) through (4), further comprising a temperature sensor provided to at least one of the intake area and the exhaust area, and built so that, according to the signal from the temperature sensor, (A) control of air flow by the air flow control means, and/or (B) control of air flow from the exhaust device via the bypass path described above to the intake device, is performed.

(6) A rack for computer storage, for installation in a building for installation and operation of computers, comprising a storage region for a computer built so as to pierce through a main body of said rack, capable of installation of a closure plate within said storage region, and built so that air flow in the direction to pierce through said rack is intercepted by the closure plate when no computer is stored in said storage region.

With the data center according to the present invention, external air that has been sucked into the intake area passes through the rack for computer storage and flows to the exhaust area, and at this time is able to abstract the heat generated by one or more computers that are stored in said rack. Since the air that has been warmed by the computers is exhausted to the exterior, accordingly the necessity for cooling this air itself is utterly nil or remarkably low. Since it is possible to build a data center that operates according to this kind of air flow control, accordingly the energy consumed by the data center is remarkably reduced, so that it may be anticipated that great cost reductions and great lessening of the burden on the environment will result. According to the present invention, there is no requirement for any complicated constructional features such as a double floor or the like for air conditioning, as was the case with a prior art data center. And the rack for computer storage according to the present invention is appropriate for application to the data center described above, since it is capable of flowing air with good efficiency to the interior of a computer that is stored in it.

Since, according to a preferred aspect of the present invention, it is possible for an operator to come and go between the intake area and the exhaust area via the airtight chamber, accordingly the working efficiency within the data center is enhanced. And, according to another preferred aspect, it is possible to increase the number of intake areas that are provided within the data center, so that it is possible to increase the number of computers that can be stored and operated. Furthermore, according to another preferred aspect, according to requirements, it is possible to take the warm air that has been exhausted back into the intake area or areas. Due to this, when the temperature is low such as at night-time or during winter or the like, it is possible to suppress overcooling of the computers and to keep the data center warm. Moreover, according to another preferred aspect, it is possible to suppress changes of temperature within the data center by controlling the air flow by utilizing feedback of a signal from a temperature sensor, and by taking in a portion of the air that has been warmed and exhausted back into the intake area.

### BRIEF DESCRIPTION OF THE DRAWINGS

The invention description below refers to the accompanying drawings, of which:

FIG. 1 is a schematic plan view of a data center which is an embodiment of the present invention;

FIG. 2 is a schematic figure showing a rack for computer storage which is an embodiment of the present invention;

FIG. 3 is a schematic plan view of a data center according to an embodiment of the present invention;

FIG. 4 is a schematic plan view of a data center according to an embodiment of the present invention; and

FIG. 5 is a schematic elevation view of a 19 inch rack that is used in the embodiments of the present invention.

### EXPLANATION OF THE REFERENCE SYMBOLS

In the drawings, 1 is a data center, 10 and 110 are intake areas, 11 and 111 are suction inlets, 20 is an exhaust area, 21 is an exhaust aperture, 12, 22, and 112 are fans, 30 is a rack for computer storage, 31 is a top plate, 32 is a side plate, 33 is a closure plate, 34 is a region in which no server is stored, 35 is a server, 36 is an air blank, 40 and 140 are dividing walls, 50 is an airtight chamber, and 13, 23, 51 and 52 are outlets and inlets.

### DESCRIPTION OF BEST MODES FOR CARRYING OUT THE INVENTION

In the following, the present invention will be explained in detail with reference to the drawings. However, the present invention is not to be considered as being limited to the embodiments shown in the figures. Since in the drawings, in some cases, one or more structural elements are depicted in an emphasized manner, accordingly the dimensions shown in the drawings are not to be considered as being limitative of the scope of the present invention.

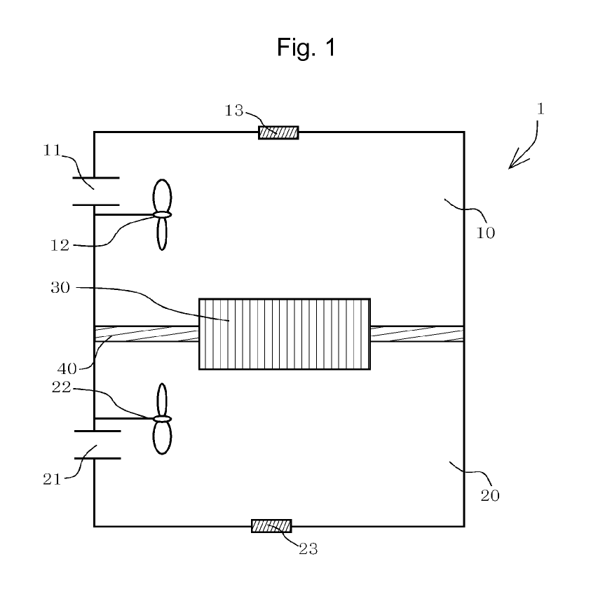

FIG. 1 is a schematic plan view of a data center according to one embodiment of the present invention. An intake area 10 and an exhaust area 20 are defined in this data center 1 by a dividing wall 40. A rack for computer storage 30 is installed in a portion of this dividing wall 40 so as to pierce through it, and this rack 30 faces both into the intake area 10 and into the exhaust area 20. With the data center of FIG. 1, external air is taken into the intake area 10 via a suction inlet 11, passes through the rack for computer storage 30 and flows into the exhaust area 20, and is discharged to the exterior via the exhaust aperture 21. In the rack for computer storage 30, desirably, the air passes through the interiors of one or more computers (not shown in the drawings) that are stored in said rack 30, and, at that time, the heat generated by the computers is abstracted by this air, so that efficient cooling of the interiors of the computers is attained. The air flow within this data center 1 is controlled by fans 12 and 22 and so on. The operator enters and leaves the intake area 10 and the exhaust area 20 through entrance/exits 13 and 23.

The intake area 10 is a region that is demarcated within the data center 1. External air is taken into this intake area 10. It is possible to incorporate any appropriate conventional air handling device as an intake device for sucking in external air; in this example, the combination of the suction inlet 11 and the fan 12 are suggested. In order to keep the interior of the data center 1 clean, a suitable filter or the like for eliminating dust may be provided to the suction inlet 11. Apart from the device for sucking in external air and the rack for computer storage 30, it is desirable for the intake area 10 not to have any other path for exit or entrance of air. Although, in order to reduce entrance and exit of air as much as possible, it is desirable for no holes or the like to be present in the floor and the ceiling and so on of the intake area 10, apertures for passing electric wiring and the like may be provided. The size of the intake area 10 is not particularly limited, as long as it is sufficiently spacious for an operator within the intake area 10 to operate the computers. In the embodiment shown in FIG. 1, an exit/entrance 13 is provided in the intake area 10 from the exterior of the building. It is desirable for this exit/entrance 13 to be built as an airlock having a plurality of doors.

The exhaust area 20 is a region that is demarcated within the data center 1, separate from the intake area 10. Air is discharged to the exterior of the data center 1 from this exhaust area 20. It is possible to incorporate any appropriate conventional air handling device as an exhaust device; in this example, the combination of the exhaust aperture 21 and the fan 22 are suggested. Apart from the exhaust device and the rack for computer storage 30, it is desirable for the exhaust area 20 not to have any other path for exit or entrance of air. Although, in order to reduce entrance and exit of air as much as possible, it is desirable for no holes or the like to be present in the floor and the ceiling and so on of the exhaust area 20, apertures for passing electric wiring and the like may be provided. The size of the exhaust area 20 is not particularly limited, as long as it is sufficiently spacious for an operator within the exhaust area 20 to operate the computers. In the embodiment shown in FIG. 1, an exit/entrance 23 is provided in the exhaust area 20 from the exterior of the building. It is desirable for this exit/entrance 23 to be built as an airlock having a plurality of doors.

The dividing wall 40 separates the intake area 10 and the exhaust area 20. The construction and the material of this dividing wall 40 are not particularly limited, provided that it is capable of intercepting flow of air between the two areas 10 and 20; conventional building board or the like may be used, as appropriate. In order to ensure the interception of air flow between the intake area 10 and the exhaust area 20, normally, the dividing wall 40 is built to extend all the way from the floor to the ceiling. The rack for computer storage 30 is installed so as to pierce through a portion of the dividing wall 40, from the intake area 10 to the exhaust area 20. Desirably, the rack for computer storage 30 constitutes the one and only flow conduit between the intake area 10 and the exhaust area 20.

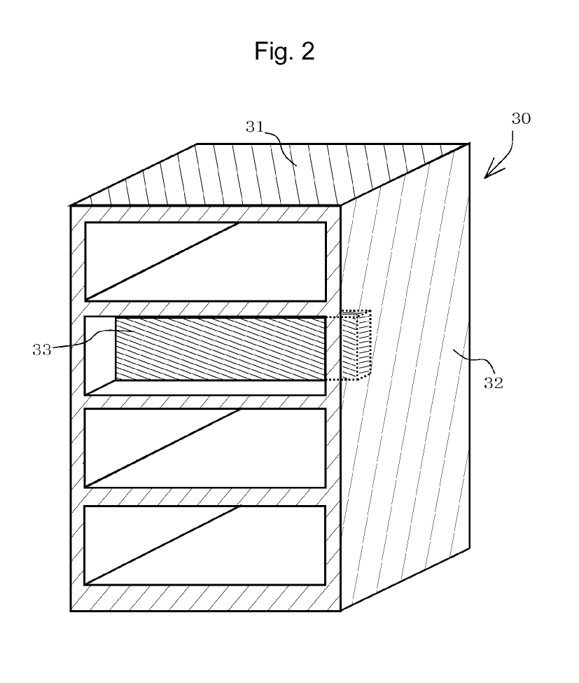

The rack for computer storage 30 (hereinafter also sometimes abbreviated as the “rack”) is a structural element built as at least one shelf, and provided with at least one region for storage of a computer that is to be operated. FIG. 2 is a schematic illustration of a rack that is one embodiment of the present invention. This rack 30 has a top plate 31 and side plates 32. Storage regions shaped as shelves are provided so as to pass through the main body of the rack 30. Computers (not shown in the figures) are stored in these shelf shaped storage regions. It is desirable for the computers that are used here to be designed for air to flow through their interiors in one axial direction. Closure plates 33 may be installed in these storage regions, so that it is possible to intercept the flow of air through those regions in the direction that they extend. If, with the rack 30 having a plurality of storage regions, computers are not stored in some of these storage regions during operation of the data center 1, then, by installing closure plates 33 in these storage regions in which computers are not stored it is possible to conduct air more efficiently to the interiors of the computers that are present, and it is possible to cool those computers more reliably.

A prior art rack for computer storage (not shown in the drawings) has no top plate 31 or side plates 32, but usually consists only of a frame. Even with this type of rack, if a structure is adopted in which it is possible to install the closure plate 33 along a prolongation of the dividing wall 40, and if it is arranged for the storage regions of the rack to be proportioned as close as possible to the computers, then efficient cooling of the computers is possible. However, if the top plate 31 and the side plates 32 are provided, then the installation conditions and the width for selection of computers for use are wider, since the control of the air flow is simpler. If any vacant space other than the computer storage regions is present in the rack 30, then it is desirable to install a blocking plate or the like in that vacant space as well, so as to ensure efficient flow of air to the interior of the computers that are stored.

According to the present invention, the type of computer that is installed and operated in the data center 1 is not particularly limited. Desirably, computers are used that are built so that cooling is provided by air flowing from the front surfaces of the computers to their rear surfaces. Even in the case of a computer of some other type, it will still be possible to anticipate a certain beneficial effect for cooling, since air in the intake area 10 will flow through the computer to the exhaust area 20.

According to the present invention, the external air that has been sucked into the intake area 10 passes through the rack for computer storage 30 and flows into the exhaust area 20. In the embodiment shown in FIG. 1, this type of air flow is controlled by the intake aperture 11, the exhaust aperture 21, and the operation of the fans 12 and 22. Accordingly, in this embodiment, it is possible to consider that the intake aperture 11, the exhaust aperture 21, and the fans 12 and 22 as constituting an air flow control means. The air flow control means is not limited to being a fan or fans; it would also be possible to use some alternative means that can create the desired air flow means in parallel therewith, or instead thereof.

It is possible to adjust the strength of the air flow as appropriate by adjusting the output of the fans or the like. According to the approach of the present inventors, it is possible to maintain the temperature internal to the computers at a temperature around 10° C. to 16° C. higher than that of the external air with a sufficient air flow. Accordingly it is possible appropriately to adjust the number of fans or the like, so that the air flow reaches a level such that this temperature region is attained in the state in which the computers are being operated.

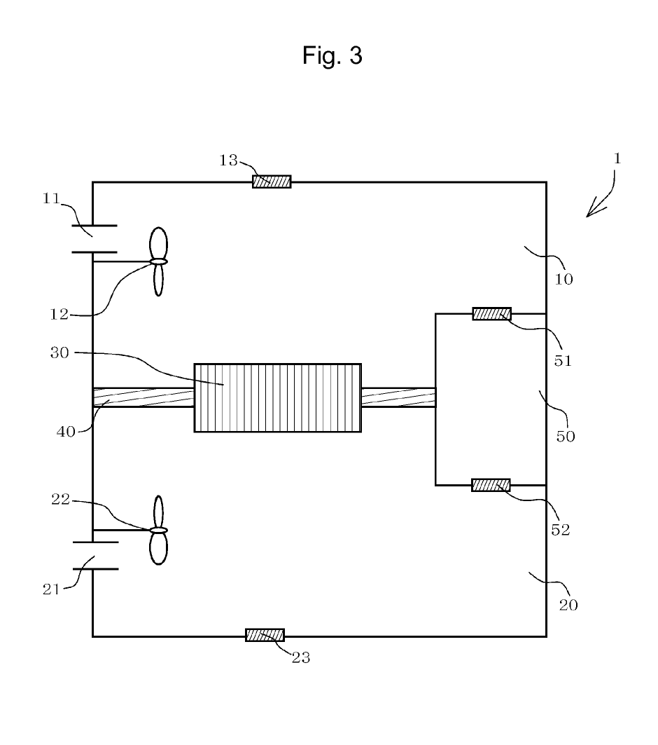

FIG. 3 is a schematic plan view of a data center that is one preferred embodiment of the present invention. With this data center 1, in addition to the intake area 10 and the exhaust area 20 described above, also an airtight chamber 50 is defined. This airtight chamber 50 is built so that flows of air both to the intake area 10 and also to the exhaust area 20 are cut off. An exit/entrance 51 to the intake area 10 and an exit/entrance 52 to the exhaust area 20 are provided to the airtight chamber 50. By taking advantage of this airtight chamber 50, it is possible for the operator to move to and fro between the intake area 10 and the exhaust area 20 without interfering with the air flow from the intake area 10 via the rack for computer storage 30 to the exhaust area 20. As a result, the working efficiently is increased, since when working upon the computers it is not necessary to go out of the data center 1 through the exit/entrance 13 or 23. With the provision of the airtight chamber 50, it is also possible to omit the installation of one or the other of the exit/entrances 13 and 23. For the design and building of the airtight chamber 50, it is possible to apply any appropriate conventional construction technique. In the present invention, the term “airtight” implies airtightness to a level that does not remarkably interfere with the flow of air passing through the rack for computer storage 30. It should be understood that, for the exit/entrances 13 and 23 of the data center 1 as well, it is desirable to construct an airtight chamber by providing a plurality of doors at each exit/entrance.

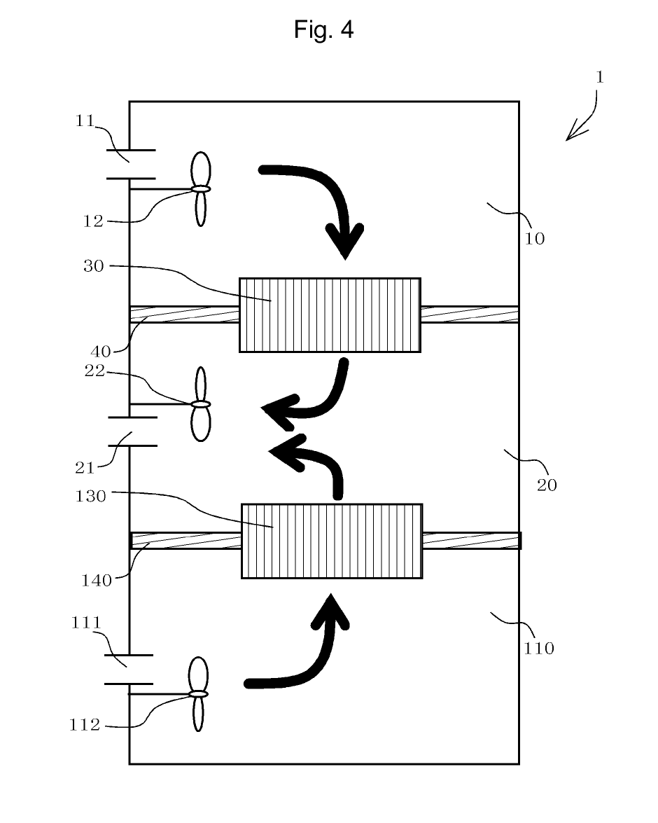

FIG. 4 is a schematic plan view of a data center that is another preferred embodiment of the present invention. In this data center 1, three areas are defined. A first intake area 10 and a second intake area 110 are present on both sides of an exhaust area 20. Air flow between the first intake area 10 and the exhaust area 20 is intercepted by a first dividing wall 40. And air flow between the second intake area 110 and the exhaust area 20 is intercepted by a second dividing wall 140. A first rack for computer storage 30 and a second rack for computer storage 130 are provided so as to pass through the first and second dividing walls 40 and 140.

The thick arrow signs in the drawing show the flows of air. The relationship between the first intake area 10 and the exhaust area 20 is the same as in the case of the embodiment shown in FIG. 1. In the embodiment of FIG. 4, sucking of external air into the second intake area 110 is enabled by the provision of a suction inlet 110 and a fan 112. This external air that has been sucked in is controlled so as to pass through the second rack for computer storage 130 and to arrive at the exhaust area 20. This type of control of the flow of air through the second intake area 110 is performed by an intake aperture 111 and the fans 112 and 22, and these may be considered as constituting a second air flow control means.

While this feature is not shown in FIG. 4, an airtight chamber of the type described above and/or exit/entrances may be provided to this data center 1 as appropriate. By providing the second intake area 110 in this manner, it is possible to increase the number of computers that are stored and that are operated in the data center 1. Moreover, by combining the data centers of the embodiments of FIGS. 1, 3, and 4 as appropriate, it is also possible to build a data center in which four or more chambers are defined.

According to the present invention, air that has been warmed by the computers is discharged from the exhaust area 20 to the exterior of the data center 1. According to yet another preferred embodiment of the present invention, a bypass path (not shown in the drawings) is provided for intake of the warm air that has been discharged into the intake area for a second time. In the prior art, there has been a tendency to consider that the more that the computers in the data center 1 are cooled, the better. However, according to the novel opinions of the present inventors, due to the recent development of computer technology, there are some cases in which it cannot be said that the amount of heat evolved from computers is necessarily very large, and also sometimes it is possible to damage computers by cooling them too much. Above all, if the temperature of the external air is remarkably low as during winter or night-time or the like, then a danger of overcooling may arise, or a requirement for heating the interior of the data center 1 may arise. In this sort of situation, a requirement can arise for increasing the temperature of the external air that is sucked into the intake area 10. In this case, it is possible to economize on energy for heating by utilizing the warm air that has been discharged from the exhaust area 20. The concrete structure of the bypass path is not particularly limited; ducts or the like may be built and used as appropriate. Moreover, in the case of the embodiment shown in FIG. 4, by using branched off ducts (not shown in the drawings), bypass paths may also be constructed from the exhaust aperture 21 of the exhaust area 20 both to the first intake area 10 and also to the second intake area 110.

Desirably, a temperature sensor (not shown in the drawings) is provided to at least one of the intake area 10 and the exhaust area 20. More desirably, the air flow within the data center is controlled according to the signal from the temperature sensor, For example, if a signal is generated that indicates that the temperature is rising, then it is possible to promote the cooling of the computers by increasing the rotational outputs of the fans 12 and 22 so that the flow of air becomes strengthened. Conversely if, according to the signal from the temperature sensor, it is recognized that sufficient cooling of the computers has been attained, then the rotational outputs of the fans 12 and 22 may be reduced, and thereby it is possible to anticipate yet further reduction of energy consumption. If a bypass path for air is provided so that it can be brought from the above described exhaust device back to the intake device, then it is also possible to heat the interior of the data center 1 by controlling the proportions of the mixture of warmed air and external air, if overcooling is recognized according to the temperature sensor. As means in concrete terms for these types of control, it is possible to incorporate appropriate known control techniques from the prior art. These inventions related to air flow control do not consider that simple cooling of the interior of the data center will be sufficient, but rather that it is better to minimize temperature variations by controlling the flow of air; and this is advocated for the first time in this proposal by the present inventors of new technical guidelines.

According to the present invention the requirement for cooling the air itself, as with a prior art data center, is nil or extremely small; however, in actual implementation of this invention, prior art techniques may be incorporated as appropriate, provided that the operation of the present invention and the benefits conferred thereby are not hindered.

### EXAMPLES

While the present invention will now be explained in greater detail in the following with reference to concrete embodiments thereof, the present invention should not be considered as being limited to those embodiments.

### Example #1

Servers were operated in an actual data center as described below. A schematic plan view of this data center is as shown in FIG. 1 and referred to above. However, in consideration of ease of working upon the servers, the intake area 10 was made larger than the exhaust area 20. In concrete terms, the intake area 10 was made of dimensions 4.5 m×2.1 m, while the exhaust area 20 was made of dimensions 4.5 m×1.0 m. A hood was provided to the intake aperture 11, and three fans 12 were installed for intake of air. The capability of these fans was as follows: pressure blades 40 cm; 1700 m³/h; 100 Pa; single phase 100 V; 135 W. And a hood was provided to the exhaust aperture 21, and three fans 22 were installed for exhaust of air. For these exhaust fans, similar fans to the intake fans described above were used. These hoods and fans served the roles of intake apparatus, exhaust apparatus, and air flow control means.

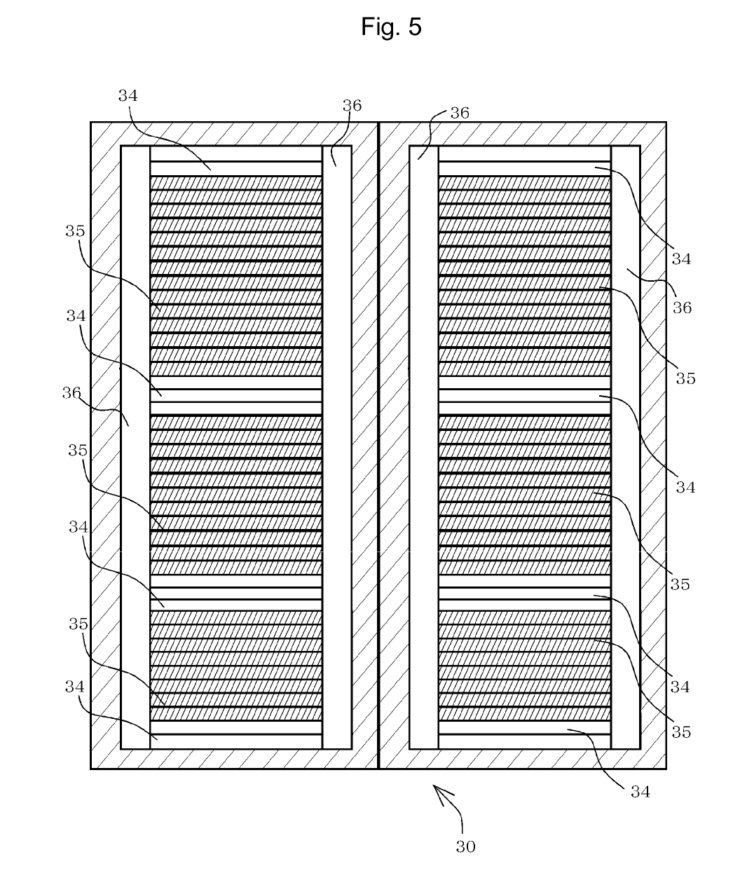

As the dividing wall 40, a fireproof wall of 12 cm thickness was installed from the floor to the ceiling. Two 19 inch racks 30 were installed so as to pierce through this dividing wall 40. These racks included top plates and side plates. FIG. 5 is a schematic elevation view of these 19 inch racks 30. Each rack 30 housed 25 IU servers 35. A number of regions 34 in which no servers 35 were housed were present in the racks 30. Panels (not shown in the drawings) were installed in these regions 34, so as to intercept flow of air from the front surfaces of the racks to their rear surfaces. Air blanks 36 were present at the outsides of the racks 30 (these were not physical elements, but regions where venting could be performed). By setting panels into these air blanks 36, flow of air from the front surfaces of the racks to their rear surfaces was intercepted.

Along with arranging to be able to monitor the temperatures of the CPUs and HDDs of the servers 35, temperature sensors were also installed to the racks 30 at their intake area sides and their exhaust area sides, so that it was arranged to be able to monitor their temperatures.

Servers were operated in this data center in Tokyo on 18 Aug. 2009. On that day the external air was at 30.1° C. (the highest temperature).

With this embodiment, the fans 12 and 22 were operated and the air flow was controlled in the state in which no exceptional load was imposed upon the CPUs and the HDDs. The temperatures of the various parts at this time were as follows:

| | Temperature | Temperature | Temperature of | | Temperature of | |
|---|---|---|---|---|---|---|
| Time | of CPUs | of HDDs | rack intake side | | rack exhaust side | |
| 12:00 | 43° C. | 37° C. | 32° | C. | 32° | C. |
| 14:00 | 43° C. | 37° C. | 32° | C. | 33.59° | C. |
| 16:00 | 42° C. | 37° C. | 32° | C. | 32° | C. |
| 18:00 | 42° C. | 35° C. | 31.2° | C. | 32° | C. |
| 20:00 | 41° C. | 35° C. | 30.56° | C. | 30.56° | C. |

### Example #2

The servers were operated in the same data center as in the case of Example #1 on another day (2 Sep. 2009). On that day the external air was at 24° C. (the highest temperature).

With this embodiment, the servers were operated in the state in which a load was imposed upon the CPUs and the HDDs. In order to impose a load upon the CPUs, a sign function was executed a million times. When this sort of load is imposed without any particular cooling measures being instituted, normally, the CPUs attain temperatures of as much as 50° C. In this Example, the air flow was controlled by operating the fans 12 and 22. The temperatures of the various parts at this time were as follows:

| | Temperature | Temperature | Temperature of | Temperature of |
|---|---|---|---|---|
| Time | of CPUs | of HDDs | rack intake side | rack exhaust side |
| 12:00 | 38° C. | 30° C. | 23.1° C. | 27.04° C. |
| 14:00 | 40° C. | 31° C. | 23.58° C. | 27.68° C. |
| 16:00 | 40° C. | 31° C. | 23.58° C. | 27.68° C. |
| 18:00 | 39° C. | 30° C. | 23.26° C. | 27.36° C. |
| 20:00 | 38° C. | 30° C. | 22.78° C. | 26.88° C. |

As described above, with Examples #1 and #2, the temperature was held stably over a long time period. In both cases, the temperature of the CPUs was maintained in a state around 10° C. to 16° C. higher than the temperature of the external air, and no further temperature increase occurred. According to current server technology, this is estimated to be an adequate temperature maintenance efficiency for withstanding actual operation. If a data center constructed as in the Examples described above were to be operated by cooling using a compressor as in the prior art, it is anticipated that an electrical power consumption of around 5,000 W to 10,000 W would be required. On the other hand, with these Examples #1 and #2, it was possible to attain temperature regulation with six fans (the maximum output of each of which was 135 W), so that according to calculation the maximum consumption of electrical power was 810 W. Thus, with Examples #1 and #2, it was possible to attain a prominent saving of electrical power in temperature management of the data center.

### POSSIBILITIES OF INDUSTRIAL APPLICATION

According to the present invention, it is possible remarkably to reduce the consumption of energy in a data center, and this is a great contribution to yet further development of information technology and yet further reduction of environmental burdens. The present application is based upon Japanese Patent Application 2009-244340, the contents of which are hereby incorporated into the present specification by reference.

What is claimed is:

1-8. (canceled)

9. A data center that is a building for installation and operation of computers, comprising:
an intake area comprising an intake device that takes external air into the building;
an exhaust area comprising an exhaust device that discharges air to the exterior of the building; a dividing wall that separates between the intake area and the exhaust area;
a rack for computer storage, installed so as to pierce through a portion of the dividing wall; and
an air flow control means that controls air flow, so as to flow air in the intake area through the rack for computer storage into the exhaust area.

10. The data center according to claim 9, further comprising an airtight chamber to which the air flow is cut off from the intake area and from the exhaust area, with the airtight chamber being provided with a exit/entrance to the intake area and an exit/entrance to the exhaust area.

11. The data center according to claim 9, further comprising a second intake area, separate from the above intake area, and comprising an intake device that takes external air into the building; a second dividing wall that separates between the second intake area and the exhaust area; a second rack for computer storage, installed so as to pierce through a portion of the second dividing wall; and a second air flow control means that controls air flow, so as to flow air in the second intake area through the second rack for computer storage into the exhaust area.

12. The data center according to claim 9, further comprising a bypass path for air from the exhaust device to the intake device.

13. The data center according to claim 10, further comprising a bypass path for air from the exhaust device to the intake device.

14. The data center according to claim 11, further comprising a bypass path for air from the exhaust device to the intake device.

15. The data center according to claim 9, further comprising a temperature sensor provided to at least one of the intake area and the exhaust area, and built so that, according to the signal from the temperature sensor, control of air flow by the air flow control means is performed.

16. The data center according to claim 10, further comprising a temperature sensor provided to at least one of the intake area and the exhaust area, and built so that, according to the signal from the temperature sensor, control of air flow by the air flow control means is performed.

17. The data center according to claim 11, further comprising a temperature sensor provided to at least one of the intake area and the exhaust area, and built so that, according to the signal from the temperature sensor, control of air flow by the air flow control means is performed.

18. The data center according to claim 12, further comprising a temperature sensor provided to at least one of the intake area and the exhaust area, and built so that, according to the signal from the temperature sensor, (A) control of air flow by the air flow control means, and/or (B) control of air flow from the exhaust device via the bypass path described above to the intake device, is performed.

19. The data center according to claim 13, further comprising a temperature sensor provided to at least one of the intake area and the exhaust area, and built so that, according to the signal from the temperature sensor, (A) control of air flow by the air flow control means, and/or (B) control of air flow from the exhaust device via the bypass path described above to the intake device, is performed.

20. The data center according to claim 14, further comprising a temperature sensor provided to at least one of the intake area and the exhaust area, and built so that, according to the signal from the temperature sensor, (A) control of air flow by the air flow control means, and/or (B) control of air flow from the exhaust device via the bypass path described above to the intake device, is performed.

21. The data center according to claim 9, wherein the rack for computer storage comprises a storage region for a computer built so as to pierce through a main body of said rack, is capable of installation of a closure plate within said storage region, and built so that air flow in the direction to pierce through said rack is intercepted by said closure plate when no computer is stored in said storage region.

22. The data center according to claim 12, wherein the rack for computer storage comprises a storage region for a computer built so as to pierce through a main body of said rack, is capable of installation of a closure plate within said storage region, and built so that air flow in the direction to pierce through said rack is intercepted by said closure plate when no computer is stored in said storage region.

23. A rack for computer storage, for installation in a building for installation and operation of computers, comprising a storage region for a computer built so as to pierce through a main body of said rack, capable of installation of a closure plate within said storage region, and built so that air flow in the direction to pierce through said rack is intercepted by said closure plate when no computer is stored in said storage region.
